(19) United States
(12) Patent Application Publication
(10) Pub. No.: US 2009/0289302 A1
(43) Pub. Date: Nov. 26, 2009

(54) SEMICONDUCTOR DEVICE AND METHOD OF FABRICATING THE SAME

(75) Inventor: Eiji MORIFUJI, Kanagawa (JP)

Correspondence Address: KNOBBE MARTENS OLSON & BEAR LLP, 2040 MAIN STREET, FOURTEENTH FLOOR, IRVINE, CA, 92614, US

(73) Assignee: KABUSHIKI KAISHA TOSHIBA, Tokyo (JP)

(21) Appl. No.: 12/463,919

(22) Filed: May 11, 2009

(30) Foreign Application Priority Data
May 9, 2008 (JP) 2008-123320

(51) Int. Cl. H01L 27/092; H01L 27/12; H01L 27/088; H01L 21/762

(52) U.S. Cl. 257/347; 257/369; 257/393; 438/424; 257/E27.062; 257/E27.112; 257/E27.06; 257/E21.546

(57) ABSTRACT

A semiconductor device 1 comprises:
a semiconductor substrate 100;
first semiconductor element regions formed on the semiconductor substrate 100 in which first semiconductor elements of first conductivity type are to be formed;
second semiconductor element regions formed on the semiconductor substrate 100 in which second semiconductor elements of second conductivity type are to be formed; and
element separation regions 120 for separating the first semiconductor element regions and the second semiconductor element regions, wherein the first semiconductor element regions are formed at the locations higher than those of the element separation regions 120 neighboring to the first semiconductor element regions.

### CROSS-REFERENCE TO RELATED APPLICATIONS

This application is based upon and claims the benefit of priority from prior Japanese Patent Application No. 2008-123320, filed on May 9, 2008, the entire contents of which are incorporated herein by reference.

### BACKGROUND

Conventionally, in Z. Krivokapic et al., IEEE International electron devices meeting (IEDM) 2003 pp. 18.5.1-18.5.4, a three dimensional semiconductor device is proposed as the size of gate width is reduced, the three dimensional semiconductor device having a structure that semiconductor element regions are formed upward from surfaces of element separation regions, and the upper side and lateral sides of silicon regions formed on the element separation regions are capable of functioning as element operation regions. For example, a semiconductor element is known, the semiconductor element having a structure that a part of the element separation region is etched and the element region is capable of being operated in three directions.

### BRIEF SUMMARY

A semiconductor device according to one embodiment of the invention comprising: a semiconductor substrate; first semiconductor element regions formed on the semiconductor substrate in which first semiconductor elements of first conductivity type are to be formed; second semiconductor element regions formed on the semiconductor substrate in which second semiconductor elements of second conductivity type are to be formed; and element separation regions for separating the first semiconductor element regions and the second semiconductor element regions, wherein the first semiconductor element regions are formed at the locations higher than those of the element separation regions neighboring to the first semiconductor element regions.

In addition, a semiconductor device according to another embodiment of the invention comprising: a semiconductor substrate; driver transistor regions formed on the semiconductor substrate in which first semiconductor elements of first conductivity type are to be formed; load transistor regions formed on the semiconductor substrate in which second semiconductor elements of second conductivity type are to be formed; and element separation regions for separating the driver transistor regions and the load transistor regions, wherein the driver transistor regions are formed at the locations higher than those of the load transistor regions.

Furthermore, a method of fabricating a semiconductor device according to another embodiment of the invention includes: preparing a semiconductor substrate; forming on the semiconductor substrate first semiconductor element regions in which first semiconductor elements of first conductivity type are to be formed, and second semiconductor element regions in which second semiconductor elements of second conductivity type are to be formed; and forming between the first semiconductor element regions and the second semiconductor element regions the element separation regions for separating the first semiconductor element regions and the second semiconductor element regions, so as to form the first semiconductor element regions at the locations higher than those of the element separation regions neighboring to the first semiconductor element regions.

### BRIEF DESCRIPTION OF THE DRAWINGS

FIG. 1A is an explanatory view showing a layout of a semiconductor device according to the first embodiment of the present invention;

FIG. 1B is an explanatory view schematically showing a macro composition of SRAM according to the first embodiment of the present invention;

FIG. 1C is an explanatory view schematically showing a composition of an LSI chip according to the first embodiment of the present invention;

FIG. 2 is a partial cross-sectional view taken along the line A-A in FIG. 1A, showing the semiconductor device according to the first embodiment of the present invention;

FIG. 3 is a partial cross-sectional view taken along the line B-B in FIG. 1A, showing the semiconductor device according to the first embodiment of the present invention;

FIG. 4 is a partial cross-sectional view taken along the line C-C in FIG. 1A, showing the semiconductor device according to the first embodiment of the present invention;

FIGS. 5A to 5F are respectively cross-sectional views showing steps of fabricating the semiconductor device according to the first embodiment of the present invention;

FIG. 6 is an explanatory view showing a layout of a semiconductor device according to the second embodiment of the present invention;

FIG. 7 is a partial cross-sectional view taken along the line D-D in FIG. 6, showing the semiconductor device according to the second embodiment of the present invention;

FIG. 8 is an explanatory view showing a layout of a semiconductor device according to the third embodiment of the present invention;

FIG. 9 is a partial cross-sectional view taken along the line E-E in FIG. 8, showing the semiconductor device according to the third embodiment of the present invention;

FIG. 10 is a partial cross-sectional view taken along the line F-F in FIG. 8, showing the semiconductor device according to the third embodiment of the present invention;

FIG. 11 is a partial cross-sectional view taken along the line G-G in FIG. 8, showing the semiconductor device according to the third embodiment of the present invention;

FIGS. 12A and 12B are respectively cross-sectional views showing steps of fabricating the semiconductor device according to the third embodiment of the present invention;

FIG. 13 is an explanatory view showing a layout of a semiconductor device according to the fourth embodiment of the present invention;

FIG. 14 is a partial cross-sectional view taken along the line H-H in FIG. 13, showing the semiconductor device according to the fourth embodiment of the present invention;

FIG. 15 is a partial cross-sectional view taken along the line I-I in FIG. 13, showing the semiconductor device according to the fourth embodiment of the present invention;

FIG. 16 is an explanatory view showing a layout of a semiconductor device according to the fifth embodiment of the present invention;

FIG. 17 is a partial cross-sectional view taken along the line J-J in FIG. 16, showing the semiconductor device according to the fifth embodiment of the present invention; and

FIG. 18 is a partial cross-sectional view taken along the line K-K in FIG. 16, showing the semiconductor device according to the fifth embodiment of the present invention.

### DETAILED DESCRIPTION

### First Embodiment

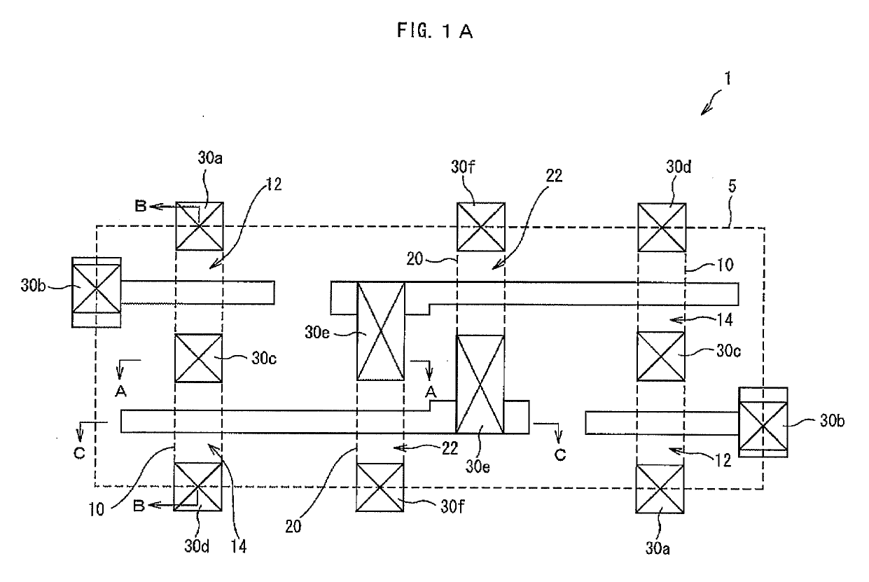

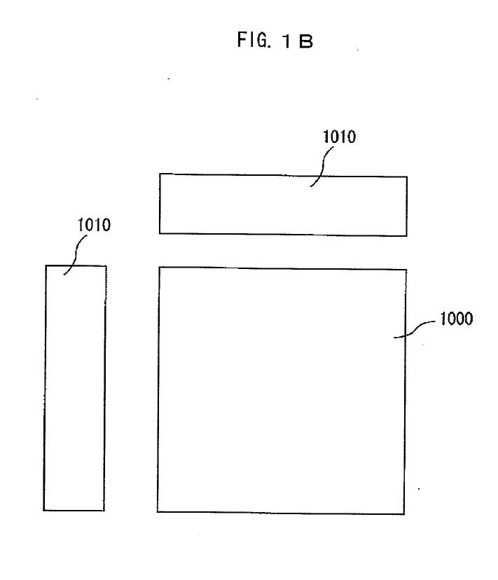

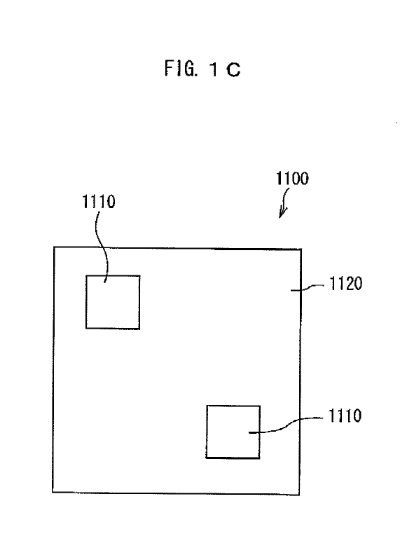

FIG. 1A is an explanatory view showing one example of a layout of the semiconductor device according to the first embodiment of the present invention.

A semiconductor device 1 according to the first embodiment includes a plurality of transistors (for example, metal oxide semiconductor field effect transistor (MOSFET) as semiconductor elements within a cell region 5 as a memory cell. The semiconductor device 1 includes NMOS regions 10 in which NMOS (NMOSFET) as the first semiconductor element of the first conductivity type (n-type) is to be formed and PMOS regions 20 in which PMOS (PMOSFET) as the second semiconductor element of the second conductivity type (p-type) different from the first conductivity type (n-type) is to be formed.

Specifically, the semiconductor device 1 includes two NMOS regions 10 having a transfer transistor region 12 and a driver transistor region 14 formed neighboring to the transfer transistor region 12, and two PMOS regions 20 having a load transistor region 22 within the cell region 5. As one example, along a longitudinal direction of the cell region 5, the first NMOS region 10, the first PMOS region 20, the second NMOS region 10 and the second PMOS region 20 are formed within the cell region 5 in this order. In the present embodiment, the transfer transistor region 12, the driver transistor region 14 and the load transistor region 22 are respectively formed in a predetermined region within the cell region 5.

The semiconductor device 1 according to the present embodiment is, as one example, static random access memory (SRAM) which includes a flip-flop circuit and a transfer gate in the predetermined region within the cell region 5 and is configured as a memory cell of six transistors type.

FIG. 1B is an explanatory view schematically showing a macro composition of SRAM according to the present embodiment of the present invention and FIG. 1C is an explanatory view schematically showing a composition of an LSI chip according to the present embodiment of the present invention.

The SRAM includes, for example as shown in FIG. 1B, a memory portion 1000 configured to have a regular layout and a peripheral logic circuit 1010 configured to have an address decoder circuit, a sense amplifier and the like. In this case, the structure of the semiconductor device 1 according to the present embodiment is applied only to the memory portion 1000 so that the logic circuit can be prevented from the change of circuit characteristics and the redesign, and the memory cell with high-performance can be realized.

Further, as shown in FIG. 1C, an LSI chip 1100 is configured to have the other circuit 1120 such as a SRAM memory macro 1110, the logic circuit, an input-output (IO) circuit and an analogue circuit. In this case, the structure of semiconductor device 1 according to the present embodiment shown in FIG. 1A can be applied to the memory portion in the SRAM memory macro 1110.

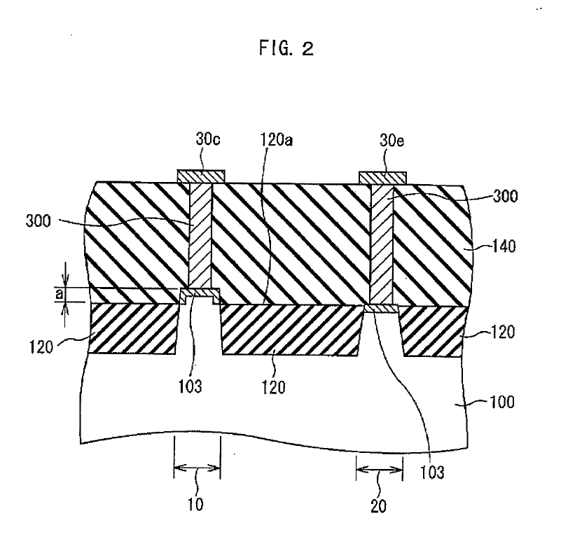

FIG. 2 is a partial cross-sectional view taken along the line A-A in FIG. 1A, showing the semiconductor device according to the first embodiment of the present invention.

The semiconductor device 1 according to the first embodiment includes a semiconductor substrate 100, silicide layers 103 formed in a predetermined region of the semiconductor substrate 100, the NMOS regions 10 formed in a predetermined region of the semiconductor substrate 100 as the first semiconductor element regions, the PMOS regions 20 formed in a predetermined region of the semiconductor substrate 100 as the second semiconductor element regions, element separation regions 120 for separating the NMOS regions 10 and the PMOS regions 20, interlayer dielectric films 140 contacting the surface of the semiconductor substrate 100 on the side where semiconductor elements are formed and simultaneously covering the semiconductor elements, and contact plugs 300 for supplying power voltage to the NMOS regions 10 and the PMOS regions 20 through contacts respectively.

In the first embodiment, the surfaces of the NMOS regions 10 are formed at the locations in the height direction different from those of the surfaces of the element separation regions 120 neighboring to the NMOS regions 10. For example, the surfaces of the NMOS regions 10 are formed at the locations higher by a predetermined amount “a” than those of the surfaces of the element separation regions 120 neighboring to the NMOS regions 10. On the other hand, the surfaces of the PMOS regions 20 are formed at the substantially same locations in height as those of the surfaces of the element separation regions 120 neighboring to the PMOS regions 20, or are formed at the locations lower than those of the surfaces of the element separation regions 120 neighboring to the PMOS regions 20.

Therefore, the heights of the NMOS regions 10 are formed higher by a predetermined amount “a” than those of the PMOS regions 20. That is, when the heights of the surface of PMOS regions 20 are defined as a reference surface, the surfaces of the NMOS regions 10 where the semiconductor elements are formed, are formed higher by the predetermined amount “a” than the reference surface. As a result, heights of channels of the NMOS regions 10 become different from heights of channels of the PMOS regions 20.

Further, if a surface of a remaining portion other than regions occupied by the NMOS regions 10 and PMOS regions 20 within the cell region 5, of the surfaces of the semiconductor substrate 100, is defined as a reference surface, the “height” in the present embodiment means, for example a height from the reference surface (that is, a distance from the reference surface). Hereinafter, the same applies to the other embodiments.

The semiconductor substrate 100 is formed of semiconductor materials having a predetermined conductivity type so as to have a predetermined thickness. The semiconductor substrate 100 is formed of, as one example, silicon (Si). Further, the semiconductor substrate 100 can be formed of a silicon germanium (SiGe) substrate, or a Silicon On Insulator (SOI) substrate. The element separation region 120 is formed, as one example, so as to have a Shallow Trench Isolation (STI) structure, and is formed of dielectric materials such as silicon dioxide (SiO₂).

The interlayer dielectric film 140 is formed of, as one example, dielectric materials such as silicon dioxide (SiO₂). The interlayer dielectric film 140 can be formed of silicon oxide such as SiOC made by adding carbon (C) to SiO₂, SiON made by adding nitrogen (N) to SiO₂, SiOF made by adding fluorine (F) to SiO₂, BPSG made by adding boron (B) and phosphorus (P) to SiO₂, and organic dielectric materials such as SiOCH, polymethylsiloxane, polyarylene, benzoxazole.

The contacts 30a to 30f are respectively formed of electrically-conductive materials so as to have a predetermined pattern. The contacts 30a to 30f are respectively formed, as one example, so as to include metal materials such as copper (Cu), aluminum (Al), gold (Au), silver (Ag) or tungsten (W). Further, the contact plugs 300 are formed, as one example, so as to include metal materials as plug materials such as Cu, Al, Au, Ag, W, molybdenum (Mo), zinc (Zn), cobalt (Co), nickel (Ni), rhodium (Rh) or iron (Fe).

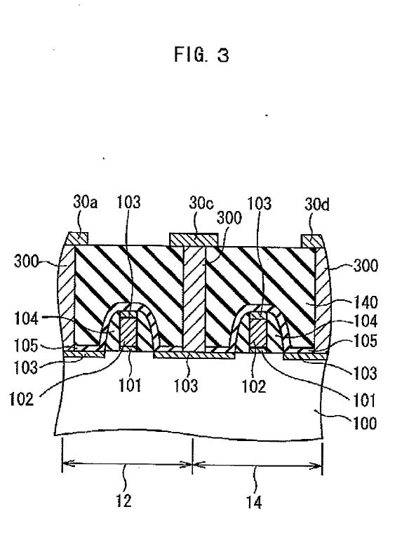

FIG. 3 is a partial cross-sectional view taken along the line B-B in FIG. 1A, showing the semiconductor device according to the first embodiment of the present invention.

In the first embodiment, the transfer transistor region 12 and the driver transistor region 14 are formed on almost the same horizontal plane. That is, if a surface of a remaining portion other than regions occupied by the NMOS regions 10 and PMOS regions 20 within the cell region 5, of the surfaces of the semiconductor substrate 100, is defined as a reference surface, the transfer transistor region 12 and the driver transistor region 14 are formed on the surfaces having almost the same height from the reference surface. And, the semiconductor elements are formed on the transfer transistor region 12 and the driver transistor region 14 respectively.

The semiconductor element includes, as one example, gate electrodes 102 formed on the surface of semiconductor substrate 100 through gate dielectric films 101, silicide region 103 formed on the opposite side of the surfaces of the gate electrodes 102 contacting the gate dielectric films 101, and gate sidewalls 104 formed on the both side surfaces of the gate dielectric films 101, the gate electrodes 102 and the silicide regions 103. And, the semiconductor element includes source drain regions (not shown) formed from neighborhood of just below of the gate sidewalls 104 in a predetermined region of the semiconductor substrate 100. And, the contact plugs 300 are respectively formed between the transfer transistor region 12 and the driver transistor region 14, and in the both sides of NMOS regions 10, and in predetermined locations of the PMOS regions 20, so as to pass through the interlayer dielectric film 140 and contact the source drain regions. Further, the semiconductor element includes liner films 105 formed on the surfaces of the silicide layers 103 and the gate sidewalls 104 other than regions where the contact plugs 300 contact with the silicide layers 103.

The gate dielectric film 101 is formed of, as one example, dielectric materials such as SiO₂, silicon nitride (SiN), SiON or high-dielectric materials (for example, Hf-based materials such as HfSiON, HfSiO, HfO, Zr-based materials such as ZrSiON, ZrSiO, ZrO, or Y-based materials such as Y₂O₃). And, the gate sidewall 104 is formed of, as one example, dielectric materials such as SiN.

The gate electrode 102 is formed of, as one example, polycrystalline silicon or polycrystalline silicon germanium containing impurities of a predetermined conductivity type. For example, if the semiconductor element is an n-type MOS, the gate electrode 102 contains n-type impurities such as arsenic (As) or P as impurities. Further, the gate electrode of a p-type FET formed on the PMOS regions 20 contains p-type impurities such as B (boron) or boron difluoride (BF₂). And, the gate electrodes 102 can be also formed of a metal gate electrode made of metal materials such as W, tantalum (Ta), titanium (Ti), hafnium (Hf) zirconium (Zr), ruthenium (Ru), platinum (Pt), iridium (Ir), Mo, or Al, or compounds of the metal materials.

The silicide regions 103 is formed of, as one example, metal materials such as Ni, Pt, Co, Er, Y, Yb, Ti or Pd, or compounds of alloy materials such as NiPt or CoNi with silicon. And, the silicide layer 103 can be formed of dielectric materials such as SiN. Further, the liner film 105 is formed of, as one example, dielectric materials such as SiN, SiO₂. And the liner film 105 can be also formed of compounds of metals such as Ni, Pt, Co, erbium (Er), yttrium (Y), ytterbium (Yb), Ti, NiPt or CoNi with silicon.

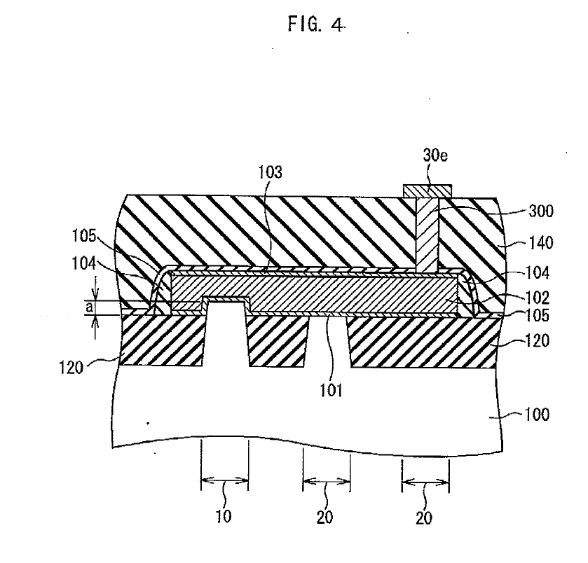

FIG. 4 is a partial cross-sectional view taken along the line C-C in FIG. 1A, showing the semiconductor device according to the first embodiment of the present invention.

In the first embodiment, the NMOS regions 10 are formed at the locations in height different from those of the PMOS regions 20, by a predetermined amount “a”. That is, the two NMOS regions 10 are formed at the locations higher than those of the two PMOS regions 20, by a predetermined amount “a”. Therefore, the surfaces of the two NMOS regions 10 are formed at the locations higher than those of the surfaces of element separation regions 120 neighboring to each NMOS regions 10, by a predetermined amount “a”, and at least in neighborhoods of the NMOS regions 10, the gate electrodes 102 have certain concavities according to the shapes of the NMOS regions 10. Further, the two NMOS regions 10 can be also formed at the locations lower than those of the two PMOS regions 20, by a predetermined amount “a”.

As a result, heights of channels of the transfer transistor regions 12 and the driver transistor regions 14 become different from heights of channels of the PMOS regions 20 (the load transistor regions 22). Particularly, in the first embodiment, channels of the transfer transistor regions 12 and the driver transistor regions 14 are formed at the locations higher than those of the load transistor regions 22.

As described above, in the first embodiment, the surfaces of the NMOS regions 10 are formed at the locations higher than those of the surfaces of the PMOS regions 20, by a predetermined amount “a”, so that the effective gate width of NMOS of the semiconductor device 1 becomes approximately equal to a width obtained by adding twice the amount “a” to the gate width of the semiconductor device 1 shown in a top view (hereinafter, referred to as “w”). That is, the surfaces of the NMOS regions 10 are formed at the locations higher than those of the surfaces of the PMOS regions 20, by a predetermined amount “a”, so that the effective gate width in the NMOS region 10 becomes approximately equal to “2a+w”, and becomes wider than the effective gate width “w” in the PMOS region 20. As a result, the channel width of the NMOS of the semiconductor device 1 becomes effectively wider than the channel width of the PMOS.

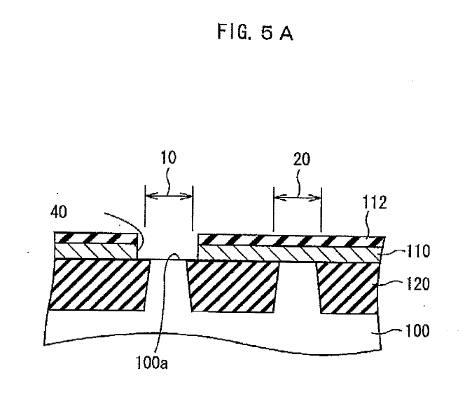

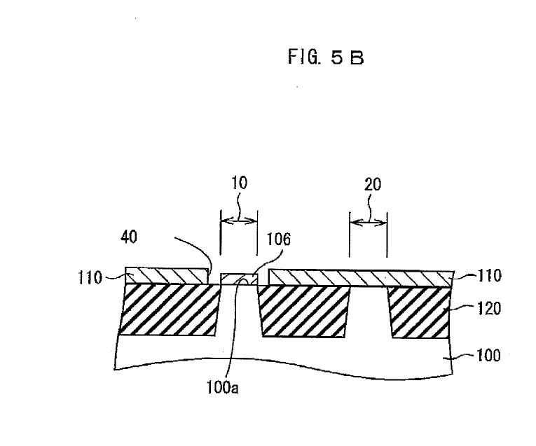

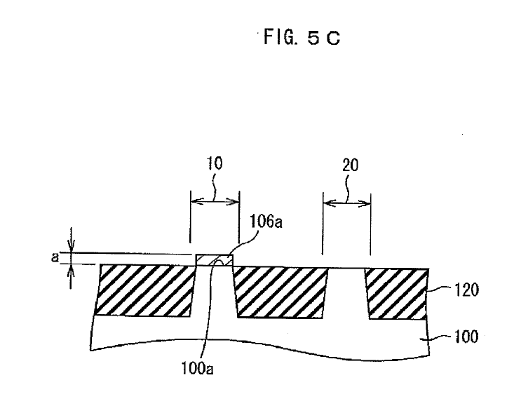

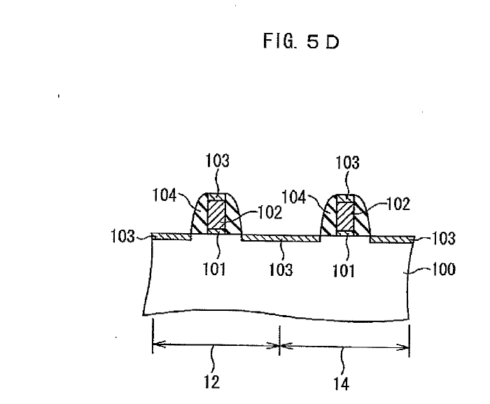

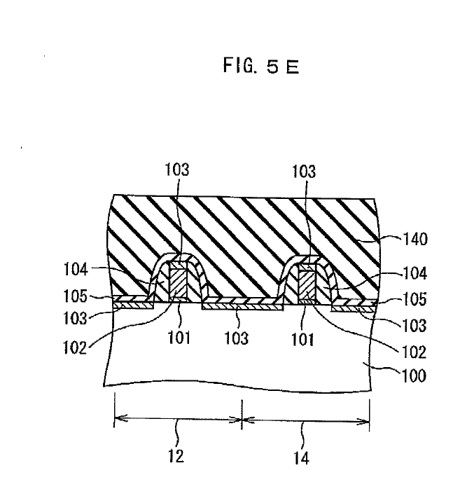

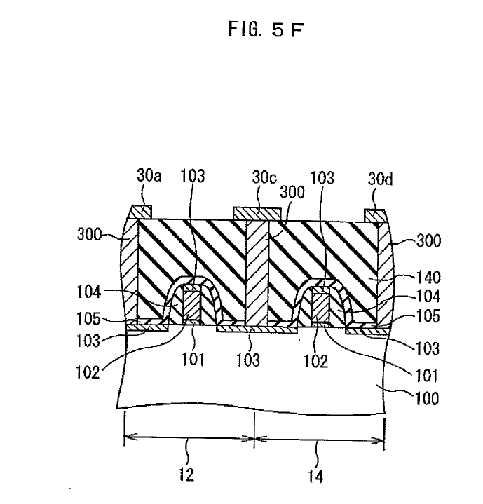

FIGS. 5A to 5F show respectively one sample of partial cross-sectional views of steps of fabricating the semiconductor device according to the first embodiment of the present invention.

Specifically, FIGS. 5A to 5C are partial cross-sectional views taken along the line A-A in FIG. 1A, showing the fabricating process, and FIGS. 5D to 5F are partial cross-sectional views taken along the line B-B in FIG. 1A, showing the fabricating process.

First, the semiconductor substrate 100 is prepared, in which the element separation regions 120 are formed on the regions other than the regions where the elements are to be formed. And, an oxide film as a protection layer 110 is formed on a silicon substrate as the semiconductor substrate 100. The oxide film is formed on the silicon substrate by carrying out a sacrifice oxidation treatment. The sacrifice oxidation treatment includes a thermal oxidation method, a chemical vapor deposition (CVD) method and the like. Subsequently, a predetermined resist 112 is coated on the protection layer 110. And, a portion of the resist 112 containing the regions where the NMOS regions 10 are to be formed is eliminated with photolithographic method. By this, a resist pattern is formed, in which a portion of the protection layer 110 containing the regions where the NMOS regions 10 are to be formed is exposed.

Next, using the formed resist pattern as a mask, the portion of the protection layer 110 containing the regions where the NMOS regions 10 are to be formed is eliminated by a wet etching treatment. For example, the portion of the protection layer 110 containing the regions where the NMOS regions 10 are to be formed is etched by using an etchant capable of etching the oxide film such as hydrofluoric acid. By this, as shown in FIG. 5A, openings 40 are formed, in which a portion of the surface of the silicon substrate containing the regions where the NMOS regions 10 are to be formed, and a part of the surface of element separation region 120 are exposed.

Next, in a state that the portion of the surface of the silicon substrate containing the regions where the NMOS regions 10 are to be formed is exposed, epitaxial growth of silicon as an epitaxial material is carried out. That is, as shown in FIG. 5B, by the selective epitaxial growth of silicon, growth layers 106 of silicon are formed on the silicon substrate exposed in the openings 40.

Next, the protection layer 110 formed on the surface of the silicon substrate is removed by an etching. As a result, as shown in FIG. 5C, convexities 106a made of silicon are formed on portions corresponding to the regions where the NMOS regions 10 are to be formed. That is, the portions of the surface of the silicon substrate corresponding to the regions where the NMOS regions 10 are to be formed, are formed at the locations higher than those of the other regions, by a predetermined amount.

In other words, the surfaces of the NMOS regions 10 are formed at the locations higher than those of the surfaces of the element separation regions 120 neighboring to the NMOS regions 10, by a predetermined amount “a”. That is, the surfaces of the NMOS regions 10 are formed at the locations higher than those of the surfaces of the PMOS region 20, by a predetermined amount “a”. Further, the predetermined amount “a” becomes approximately equal to the film thickness of silicon epitaxially grown on the silicon substrate in FIG. 5B.

Further, for example, if the gate width is 90 nm, the predetermined amount “a” can be configured to be more than 5 nm as one example. And, the predetermined amount “a” is configured to be not more than the gate width. Here, the predetermined amount “a” is not particularly limited in not less than 5 nm, if it has such a height as an influence of variations in height which occur in the fabricating process of the semiconductor device 1 can be substantially disregarded. For example, according to reduction of the gate width, the surfaces of the NMOS regions 10 are formed at the locations higher than those of the surfaces of the element separation regions 120 neighboring to the NMOS regions 10, so that the effective gate width, that is, the channel width of the NMOS is significantly enlarged, even if the predetermined amount “a” is a small amount.

Next, as shown in FIG. 5D, n-type MOSFET and p-type MOSFET are formed on each of the NMOS regions 10 and the PMOS regions 20. That is, NMOSFET as the transfer transistor is formed on the transfer transistor regions 12 of the NMOS regions 10, and simultaneously, NMOSFET as the driver transistor is formed on the driver transistor regions 14 of the NMOS regions 10. Further, PMOSFET as the load transistor is formed on the load transistor regions 22 of the PMOS regions 20.

Specifically, the gate electrodes 102 are formed on each of the transfer transistor regions 12 and the driver transistor regions 14 of the silicon substrate through the gate dielectric films 101. Subsequently, the gate sidewalls 104 are formed on the both sidewalls of the gate dielectric films 101 and the gate electrodes 102. The gate dielectric films 101, the gate electrodes 102 and the gate sidewalls 104 are formed by using the thermal oxidation method and the CVD method, and a photolithography method.

Next, the silicide layers 103 are formed on the gate electrodes 102 and the semiconductor substrate 100 being exposed. The silicide layers 103 are formed, as one example, as follows. First, a predetermined metal film is formed on the top surfaces of the gate electrodes 102 by using a sputtering method and the like. After that, a predetermined thermal treatment such as a rapid thermal annealing (RTA) is performed for the formed metal film, and chemical reaction to form silicide region is carried out between the metal film and the gate electrodes 102. As a result, the silicide layers 103 can be formed.

Next, as shown in FIG. 5E, a liner film 105 and an interlayer dielectric film 140 are formed. Specifically, the liner film 105 is formed on the surfaces of the silicide layers 103 other than the regions where the MOSFET is formed and the surface of the MOSFET (the surfaces of the silicide layers 103 and the gate sidewalls 104) so as to have a predetermined film thickness. The liner film 105 is formed by the CVD method and the like. Further, the interlayer dielectric film 140 is also formed by the CVD method and the like as in the case of the liner film 105.

Next, holes for plug are formed by eliminating portions of the interlayer dielectric film 140 and the liner film 105, which correspond to the places where the contact plugs 300 are formed, by using the photolithography method and a reactive ion etching polishing (RIE) method. Subsequently, a plug material for forming the contact plugs 300 is filled into the holes for plug and simultaneously is deposited on the interlayer dielectric film 140. The plug material deposited on the interlayer dielectric film 140 is subjected to a planarization treatment by using a chemical mechanical polishing (CMP) method and the like, while the top surface of interlayer dielectric film 140 is used as a stopper, so that the plug material is fabricated to the contact plugs 300.

Subsequently, contacts 30a to 30g are formed by using the photolithography method, the RIE method, the sputtering method and the like. By this, as shown in FIG. 5F, the semiconductor device 1 according to the first embodiment is formed.

According to the first embodiment, the surfaces of the NMOS regions 10 can be formed at the locations higher than those of the surfaces of the PMOS region 20, by a predetermined amount “a”, so that the effective gate widths of the NMOS of the semiconductor device 1 can be wider than those of the PMOS. As a result, according to the first embodiment, the drivability of the NMOS can be enhanced without reducing the threshold voltage. That is, according to the semiconductor device 1 of the first embodiment, cell current can be increased without increasing cell area, and cell switching speed can be improved and stable read operation can be ensured in spite of the leakage of bit-lines. Further, the surfaces of the PMOS regions 20 are formed at almost the same locations in height as those of the surfaces of the element separation regions 120, so that reduction of writing margin due to enhancement of the drivability does not substantially occur.

Further, according to the first embodiment, the property of each semiconductor element can be optimized in one cell, for example, without changing the layout pattern of the SRAM preliminarily determined, that is, only by changing the location in height of the surface of the NMOS region 10 without increasing the area of the cell region 5. That is, according to the semiconductor device 1 of the first embodiment, regularity of the layout of the SRAM is kept and simultaneously the location in height of the surface of the NMOS region 10 is adjusted in the fabricating process, so that a plurality of the MOSFETs having different property respectively can be formed in one cell region 5. Therefore, it is not needed to design a new layout pattern and to fabricate a mask corresponding to the new layout pattern, so that the property of the SRAM can be enhanced by a simple process without increasing the production cost.

### Second Embodiment

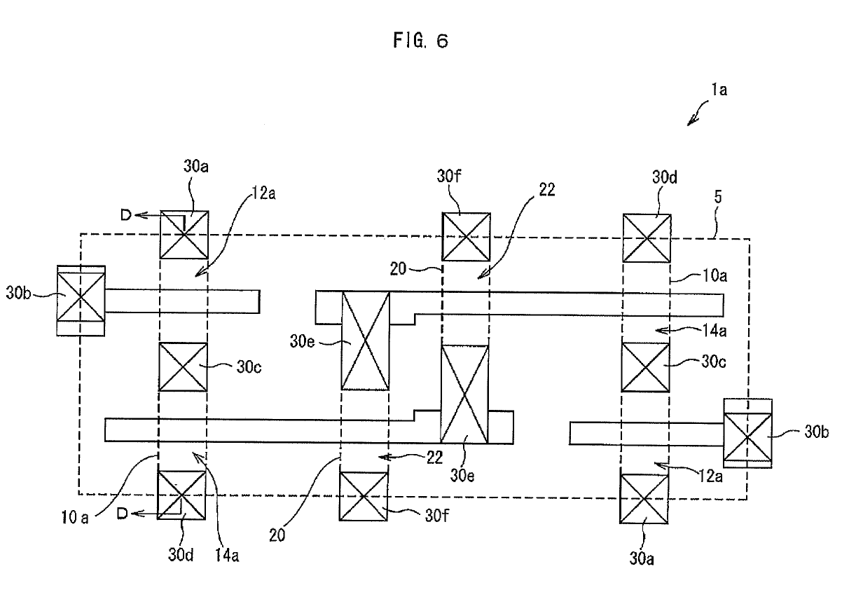

FIG. 6 is an explanatory view showing one example of a layout of a semiconductor device according to the second embodiment of the present invention.

A semiconductor device 1a according to the second embodiment includes almost the same composition as the semiconductor device 1 according to the first embodiment except that the surfaces of the driver transistor regions 14a are formed at the locations higher than those of the surfaces of the transfer transistor regions 12a. Therefore, detail explanation about almost the same composition as the first embodiment is omitted.

A semiconductor device 1a according to the second embodiment includes NMOS regions 10a in which NMOS is to be formed and PMOS regions 20 in which PMOS is to be formed within the cell region 5. And, the semiconductor device 1a includes two NMOS regions 10a having a transfer transistor region 12a and a driver transistor region 14a, and two PMOS regions 20 having a load transistor region 22 within the cell region 5. Here, in the second embodiment, the surfaces of the driver transistor regions 14a are formed at the locations higher than those of both the surfaces of the transfer transistor regions 12a and the load transistor regions 22.

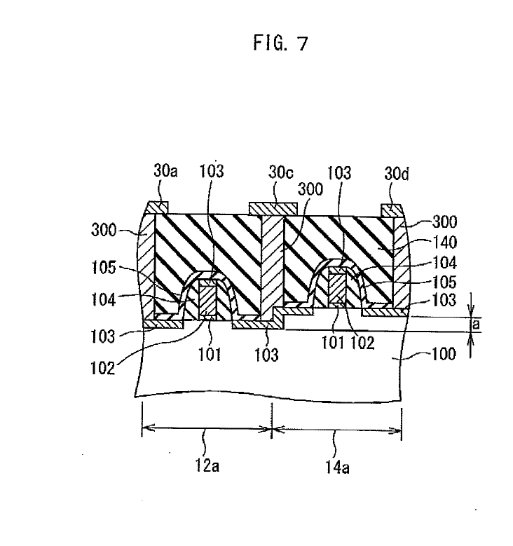

FIG. 7 is a partial cross-sectional view taken along the line D-D in FIG. 6, showing the semiconductor device according to the second embodiment of the present invention.

In the second embodiment, the surfaces of the driver transistor regions 14a are formed at the locations in height different from those of the surfaces of the element separation regions 120 neighboring to the NMOS regions 10a and the transfer transistor regions 12a. For example, the surfaces of the driver transistor regions 14a are formed at the locations higher by a predetermined amount “a” than those of the surfaces of the element separation regions 120 neighboring to the NMOS regions 10a and the transfer transistor regions 12a. And, the surfaces of the driver transistor regions 14a are formed at the locations higher by a predetermined amount “a” than those of the surfaces of the PMOS regions 20.

The driver transistor regions 14a according to the second embodiment can be formed by that, for example, epitaxial growth of silicon is carried out in the regions corresponding to the driver transistor regions 14a, in the processes of FIGS. 5A to 5B with regard to the explanation of the method of fabricating the semiconductor device 1 according to the first embodiment. The other processes are almost the same as those of the first embodiment.

According to the second embodiment, the surfaces of the driver transistor regions 14a which the NMOS regions 10 includes can be formed at the locations higher than those of the surfaces of the transfer transistor regions 12a and the PMOS region 20, by a predetermined amount “a”, so that the effective gate widths of the driver transistors of the semiconductor device 1a can be wider than those of the transfer transistors and the load transistors without increasing the cell area. As a result, according to the semiconductor device 1a of the second embodiment, the driving force of the driver transistors can be enhanced without reducing the threshold voltage.

Further, according to the second embodiment, the surfaces of the driver transistor regions 14a can be formed at the locations higher than those of the transfer transistor regions 12a by a predetermined amount “a”, so that the cell current can be ensured and simultaneously, a value (β ratio) which is obtained by dividing the drivability of the driver transistors by the drivability of the transfer transistors can be increased, and noise margin at read operation can be ensured, without increasing the cell area and with retaining the regularity of the SRAM.

### Third Embodiment

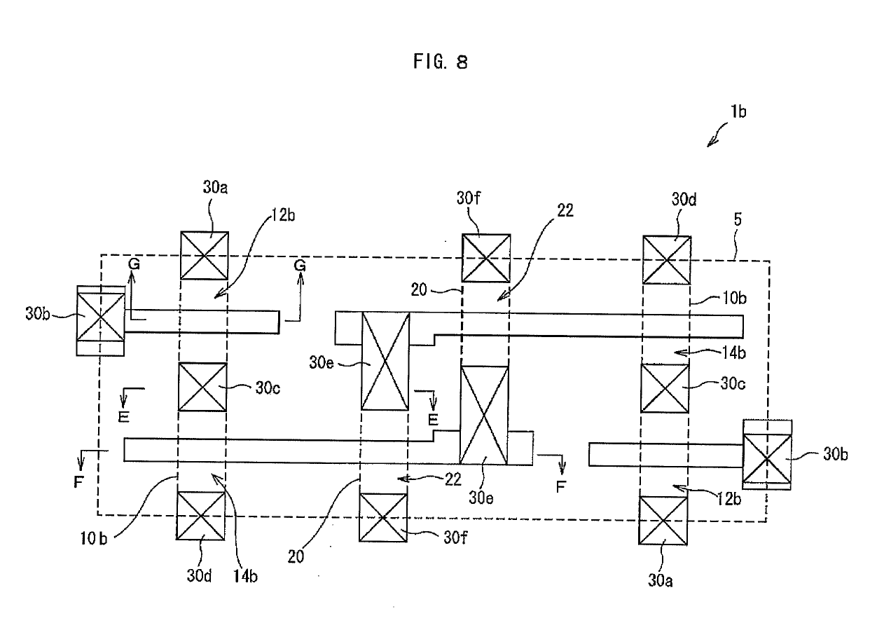

FIG. 8 is an explanatory view showing one example of a layout of a semiconductor device according to the third embodiment of the present invention.

A semiconductor device 1b according to the third embodiment includes almost the same composition as the semiconductor device 1 according to the first embodiment except that the surfaces of predetermined regions of the element separation regions 120 including the element separation regions 120 neighboring to the NMOS regions 10b is eliminated by a predetermined thickness. Therefore, detail explanation about almost the same composition as the first embodiment is omitted.

A semiconductor device 1b according to the third embodiment includes NMOS regions 10b in which NMOS is to be formed and PMOS regions 20 in which PMOS is to be formed within the cell region 5. And, the semiconductor device 1b includes two NMOS regions 10b having a transfer transistor region 12b and a driver transistor region 14b, and two PMOS regions 20 having a load transistor region 22 within the cell region 5. Here, in the third embodiment, the surfaces of the NMOS regions 10b and the PMOS regions 20 are formed on almost the same horizontal plane. Further, the surfaces of the element separation regions 120 including at least the element separation regions 120 neighboring to the NMOS regions 10b are removed by a predetermined thickness.

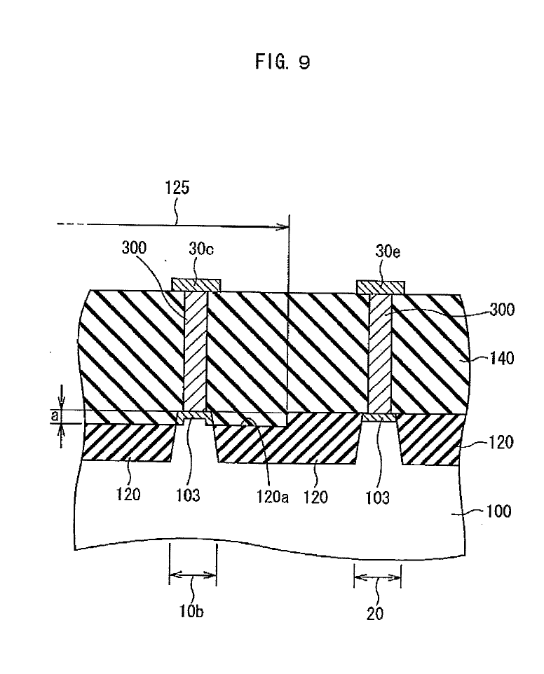

FIG. 9 is a partial cross-sectional view taken along the line E-E in FIG. 8, showing the semiconductor device according to the third embodiment of the present invention.

In the third embodiment, the surfaces of the element separation regions 120 neighboring to the NMOS regions 10b are formed at the locations in height different from those of the surfaces of the NMOS regions 10b. Specifically, the surfaces 120a of the element separation regions 120 including at least the element separation regions 120 neighboring to the NMOS regions 10b are formed at the locations lower than the surfaces of the NMOS regions 10b, by a predetermined amount “a”. That is, in the third embodiment, the surfaces of the NMOS regions 10b are formed at almost the same locations in height as the surfaces of the PMOS regions 20, on the other hand, the surfaces of the element separation regions 120 neighboring to the NMOS regions 10b are eliminated in height by the predetermined amount “a”, so that the surfaces of the NMOS regions 10b are formed at the locations relatively higher than those of the surfaces 120a of the element separation regions 120 neighboring to the NMOS regions 10b by the predetermined amount “a”. As a result, the element separation regions 120 in neighborhoods of the NMOS regions 10b have concavity regions 125 trenched by the predetermined amount “a”.

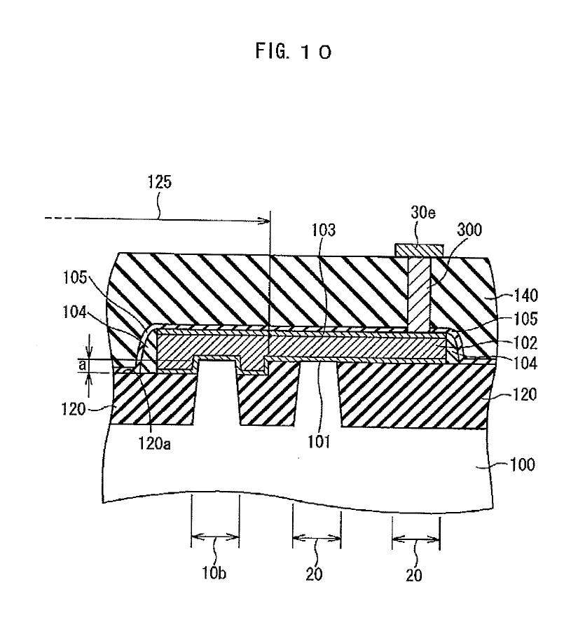

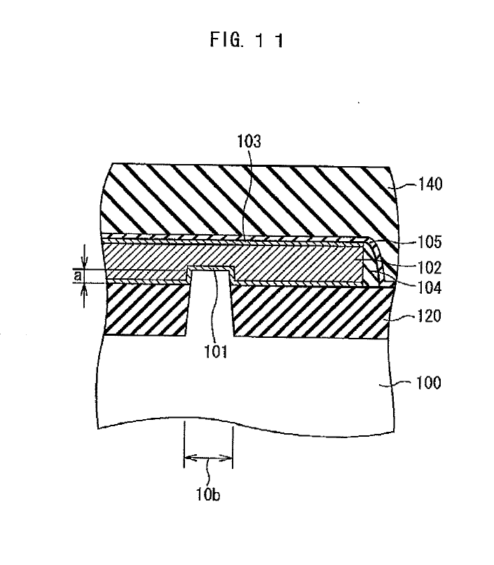

FIG. 10 is a partial cross-sectional view taken along the line F-F in FIG. 8, showing the semiconductor device according to the third embodiment of the present invention. Further, FIG. 11 is a partial cross-sectional view taken along the line G-G in FIG. 8, showing the semiconductor device according to the third embodiment of the present invention.

With reference to FIG. 10, the surfaces of the NMOS regions 10b and the PMOS regions 20 are formed on almost the same horizontal plane. On the other hand, the surfaces 120a of the element separation regions 120 neighboring to the NMOS regions 10b and including the neighborhood of the NMOS regions 10b are formed at the locations lower than the surfaces of the NMOS regions 10b by the predetermined amount “a”. Similarly, with reference to FIG. 11, the surfaces 120 of the element separation regions 120 neighboring to the NMOS regions 10b and including the neighborhood of the NMOS regions 10b corresponding to the transfer transistor regions 12b are also formed at the locations lower than the surfaces of the NMOS regions 10b by the predetermined amount “a”.

Therefore, the surfaces of the two NMOS regions 10b are formed at the locations relatively higher than those of the surfaces 120a of the element separation regions 120 neighboring to each NMOS region 10b by the predetermined amount “a”, and at least in the neighborhood of the NMOS regions 10b, the gate electrodes 102 are formed so as to have significant concavities corresponding to the shape of the NMOS region 10.

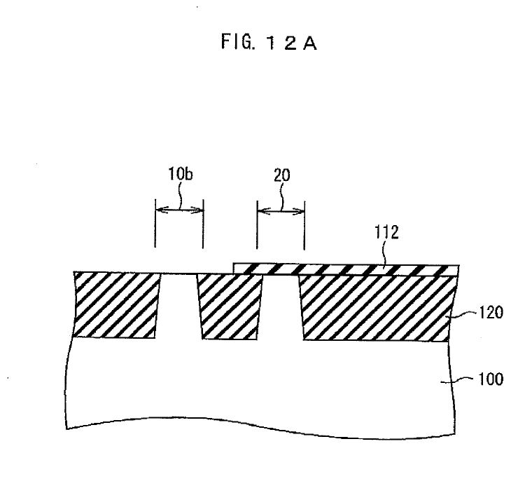

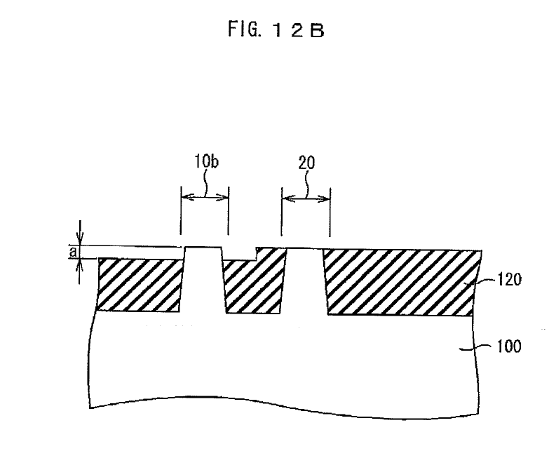

FIGS. 12A and 12B are respectively one example of cross-sectional views showing steps of fabricating the semiconductor device according to the third embodiment of the present invention.

First, the element separation regions 120 for separating the NMOS regions 10b and the PMOS regions 20 are formed on a silicon substrate as the semiconductor substrate 100. And, as shown in FIG. 12A, a pattern having a shape that the surfaces of the element separation regions 120 neighboring to the NMOS regions 10b are at least exposed is formed by a predetermined resist 112.

Next, using the pattern formed by the resist 112 as a mask, the element separation regions 120 are subjected to a selective etching treatment. That is, a portion of the element separation regions 120 is etched and eliminated selectively to the semiconductor substrate 100. As the selective etching treatment, a wet etching treatment or a dry wet etching treatment can be used. And, after the selective etching treatment is completed, the pattern formed by the resist 112 is eliminated. As a result, as shown in FIG. 12B, the surfaces of the element separation regions 120 neighboring to the NMOS regions 10b are eliminated by a predetermined thickness “a”.

Fabricating processes after the process shown in FIG. 12B are almost the same as those of the semiconductor device 1 according to the first embodiment, so that the explanation is omitted.

### Fourth Embodiment

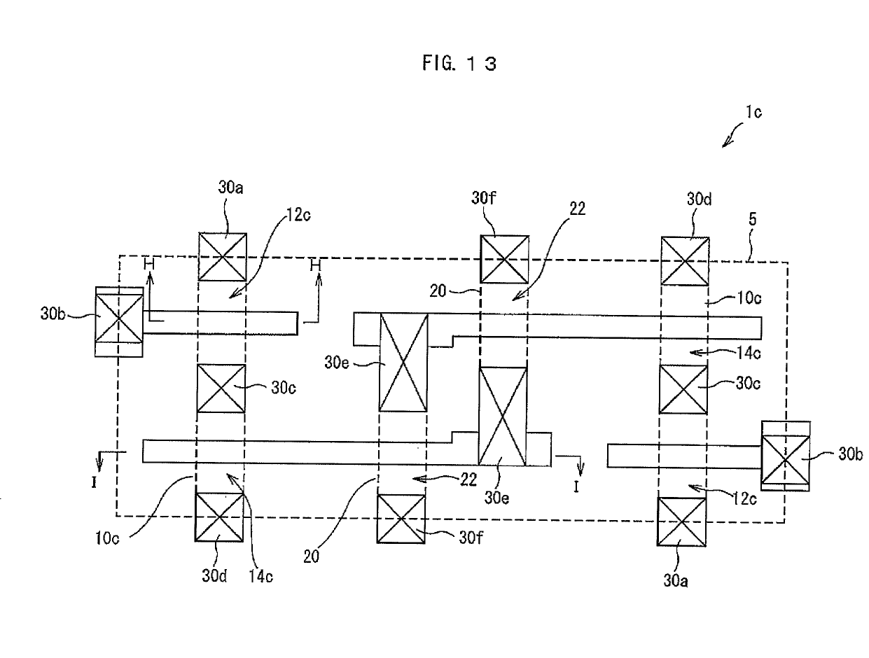

FIG. 13 is an explanatory view showing one example of a layout of a semiconductor device according to the fourth embodiment of the present invention.

A semiconductor device 1c according to the fourth embodiment includes almost the same composition as the semiconductor device 1b according to the third embodiment except that the surfaces of the element separation regions 120 neighboring to the driver transistor regions 14a are eliminated by a predetermined thickness “a”. Therefore, detail explanation about almost the same composition as the third embodiment is omitted.

A semiconductor device 1c according to the fourth embodiment includes NMOS regions 10c in which NMOS is to be formed and PMOS regions 20 in which PMOS is to be formed within the cell region 5. And, the semiconductor device 1c includes two NMOS regions 10b having a transfer transistor region 12c and a driver transistor region 14c, and two PMOS regions 20 having a load transistor region 22 within the cell region 5. Here, in the fourth embodiment, the surfaces of the transfer transistor regions 12c of the NMOS regions 10c and the PMOS regions 20 are formed on almost the same horizontal plane. On the other hand, the surfaces of the element separation regions 120 including at least the element separation regions 120 neighboring to the driver transistor regions 14c of the NMOS regions 10c are removed by a predetermined thickness.

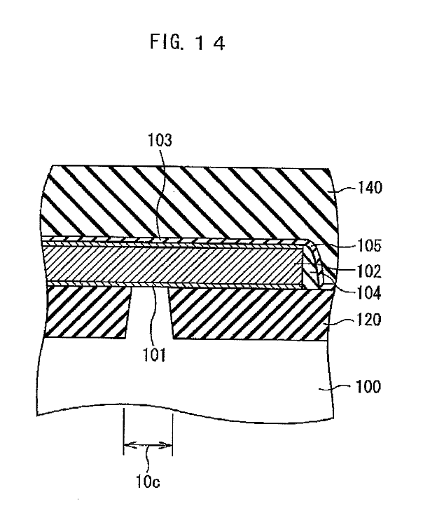

FIG. 14 is a partial cross-sectional view taken along the line H-H in FIG. 13, showing the semiconductor device according to the fourth embodiment of the present invention.

In the semiconductor device 1c according to the fourth embodiment, the surfaces of the element separation regions 120 neighboring to the driver transistor regions 14c are eliminated by a predetermined thickness, the other hand, the surfaces of the element separation regions 120 neighboring to the transfer transistor regions 12c are not eliminated. Therefore, as shown in FIG. 14, the surfaces of the transfer transistor regions 12c and the element separation regions 120 neighboring to the transfer transistor regions 12c are formed on almost the same horizontal plane.

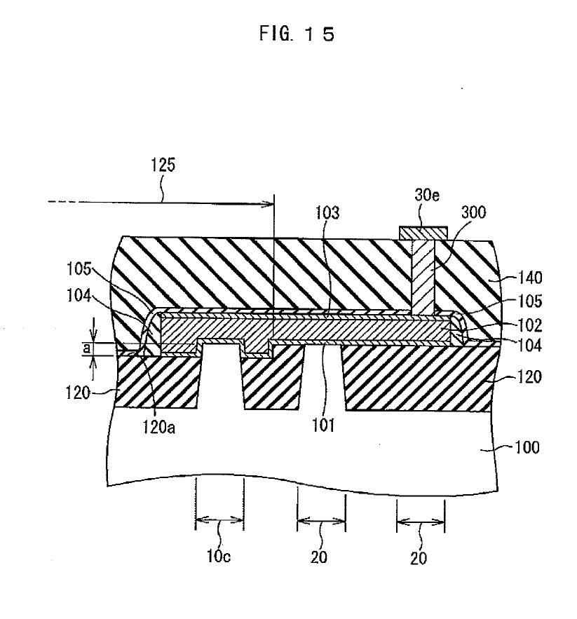

FIG. 15 is a partial cross-sectional view taken along the line I-I in FIG. 13, showing the semiconductor device according to the fourth embodiment of the present invention.

With reference to FIG. 15, the surfaces of the NMOS regions 10c and the PMOS regions 20 are formed on almost the same horizontal plane. On the other hand, the surfaces of the element separation regions 120 neighboring to the NMOS regions 10c and including the neighborhood of the NMOS regions 10c are formed at the locations lower than the surfaces of the NMOS regions 10c by the predetermined amount “a”.

### Fifth Embodiment

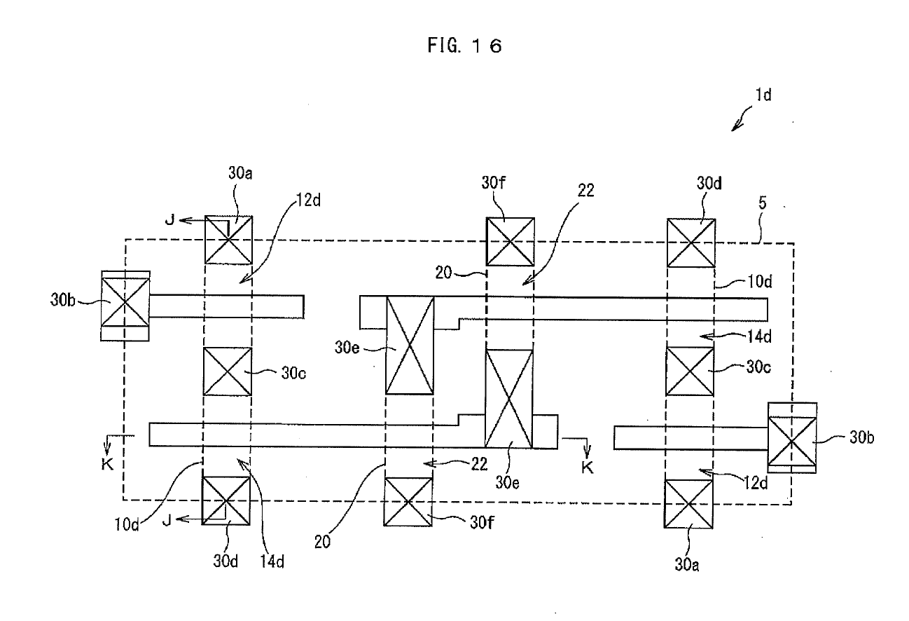

FIG. 16 is an explanatory view showing one example of a layout of a semiconductor device according to the fifth embodiment of the present invention.

The semiconductor device 1d according to the fifth embodiment is formed so as to have a composition that the respective heights of the driver transistor region 14d, the transfer transistor region 12d and the load transistor region 22 become gradually lower in this order. The other compositions are almost the same as those of the semiconductor device 1 according to the first embodiment, so that detail explanation is omitted.

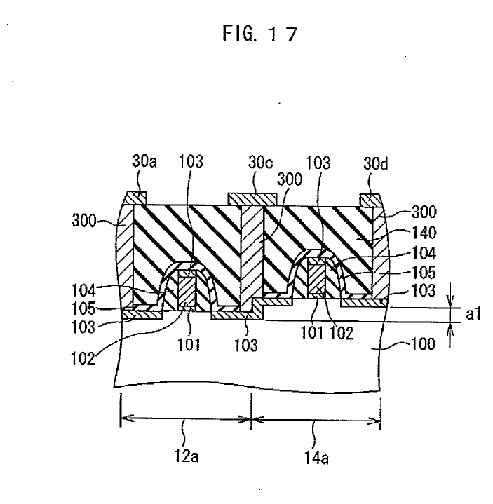

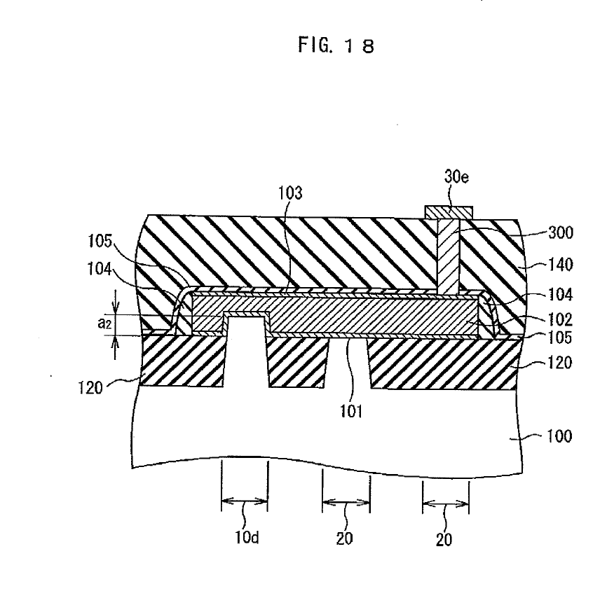

FIG. 17 is a partial cross-sectional view taken along the line J-J in FIG. 16, showing the semiconductor device according to the fifth embodiment of the present invention. And, FIG. 18 is a partial cross-sectional view taken along the line K-K in FIG. 16, showing the semiconductor device according to the fifth embodiment of the present invention.

In the semiconductor device 1d according to the fifth embodiment, as shown in FIG. 17, the surfaces of the driver transistor regions 14d are formed at the locations higher than those of the surfaces of the transfer transistor regions 12d by the predetermined amount “a1”. And, as shown in FIG. 18, the surfaces of the driver transistor regions 14d of the NMOS regions 10d are formed at the locations higher than those of the surfaces of the PMOS regions 20 by the predetermined amount “a2”.

In the fifth embodiment, the predetermined amount “a2” is formed higher than the predetermined amount “a1”. As a result, in the cell region 5, the surfaces of the driver transistor regions 14d are formed at the locations higher than those of both the surfaces of the transfer transistor regions 12d and the PMOS regions 20. Further, the surfaces of the PMOS regions 20 (the surfaces of the load transistor regions 22) are formed at the locations lower than those of both the surfaces of the driver transistor regions 14d and the transfer transistor regions 12d.

In the fifth embodiment, the heights of driver transistor region 14d, transfer transistor region 12d and the load transistor region 22 are respectively changed, but it can be also used that the heights of driver transistor region 14d, transfer transistor region 12d and the load transistor region 22 are respectively kept approximately constant and the removal amount of the element separation regions 120 neighboring to the respective regions are respectively changed. For example, the semiconductor device can be formed so as to have a composition that the removal amount of the element separation regions 120 respectively neighboring to the driver transistor regions 14d, the transfer transistor regions 12d and the load transistor regions 22 are gradually reduced in this order.

In the first to the fifth embodiments, the layout of the SRAM shown in FIG. 1A is used, but the layout of the SRAM is not limited to the layout. Further, it can be also used that the surfaces of the NMOS regions 10 within the cell region 5 are formed at the locations higher (or the surfaces of the element separation regions 120 neighboring to the NMOS regions 10 are formed at the locations lower) and simultaneously the surfaces of the PMOS regions 20 outside the cell region 5 are formed at the locations higher, or the surfaces of the element separation regions 120 neighboring to the PMOS regions 20 outside the cell region 5 are formed at the locations lower than those of the surfaces of the PMOS regions 20, so that the drivability of the PMOS outside the cell region 5 is enhanced and the writing margin of the SRAM is ensured.

Further, in the first to the fifth embodiments, the embodiment of the SRAM as the semiconductor device has been described, but the semiconductor device is not limited the SRAM, as long as in a predetermined cell region including a plurality of the semiconductor elements, the properties of the respective semiconductor elements can be configured individually. For example, the semiconductor device can be configured as a device including the MOSFET, the PMOS the NMOS or the like.

As seen above, the embodiments have been explained, but it should be noted that embodiments described above do not limit the inventions according to the scopes of the claims. And, all combinations of features explained in the embodiments are not always essential for means for solving the problems in the invention.

What is claimed is:

1. A semiconductor device, comprising:
a semiconductor substrate;
first semiconductor element regions on the semiconductor substrate configured to comprise first semiconductor elements of first conductivity type;
second semiconductor element regions on the semiconductor substrate configured to comprise second semiconductor elements of second conductivity; and
element separation regions between the first semiconductor element regions and the second semiconductor element regions, wherein the first semiconductor element regions are at the locations higher than those of the element separation regions next to the first semiconductor element regions.

2. The semiconductor device of claim 1, wherein the distances from the surfaces of the element separation regions to the surfaces of the first semiconductor element regions are kept shorter than gate widths of the first semiconductor element regions from a top view.

3. The semiconductor device of claim 1, wherein the first semiconductor element regions are at the locations higher than those of the second semiconductor element regions.

4. The semiconductor device of claim 1, wherein the second semiconductor element regions are at the substantially same locations in height as those of the element separation regions next to the second semiconductor element regions.

5. The semiconductor device of claim 1, wherein the second semiconductor element regions are at the locations lower than those of the element separation regions next to the second semiconductor element regions.

6. The semiconductor device of claim 1, wherein the first semiconductor element regions are NMOS regions and the second semiconductor element regions are PMOS regions.

7. The semiconductor device of claim 6, wherein the NMOS regions comprise transfer transistor regions and driver transistor regions at the locations next to the transfer transistor regions and the PMOS regions comprise load transistor regions.

8. A semiconductor device, comprising:
a semiconductor substrate;
driver transistor regions on the semiconductor substrate configured to comprise first semiconductor elements of first conductivity type;
load transistor regions on the semiconductor substrate configured to comprise second semiconductor elements of second conductivity type; and
element separation regions between the driver transistor regions and the load transistor regions, wherein the driver transistor regions are at the locations higher than those of the load transistor regions.

9. The semiconductor device of claim 8, further comprising gate electrodes on the driver transistor regions and the load transistor regions through gate dielectric films, and channels of the driver transistor regions and the load transistor regions located in the semiconductor substrate below the gate electrodes, wherein
the channels of the driver transistor regions comprise channel widths substantially wider than those of the channels of the load transistor regions as a result of that the driver transistor regions are at the positions higher than those of the load transistor regions.

10. The semiconductor device of claim 8, further comprising transfer transistor regions at the locations next to the driver transistor regions, wherein
the transfer transistor regions and the driver transistor regions are on a horizontal plane.

11. The semiconductor device of claim 8, further comprising transfer transistor regions at the locations next to the driver transistor regions, wherein
the driver transistor regions are at the locations higher than those of the transfer transistor regions.

12. The semiconductor device of claim 8, wherein the semiconductor substrate is selected from either a silicon substrate, a silicon germanium substrate, or a Silicon On Insulator substrate.

13. The semiconductor device of claim 9, wherein the gate dielectric films comprise either silicon dioxide (SiO₂), silicon nitride (SiN), silicon oxynitride (SiON), hafnium silicon oxynitride (HfSiON), hafnium silicon oxide (HfSiO), hafnium oxide (HfO), zirconium silicon oxide nitride (ZrSiON), zirconium silicon oxide (ZrSiO), zirconium oxide (ZrO), or yttrium oxide (Y₂O₃).

14. The semiconductor device of claim 9, wherein the gate electrodes comprise either polycrystal silicon or polycrystal silicon germanium.

15. The semiconductor device of claim 9, wherein the gate electrodes comprise at least one metal material selected from tungsten (W), tantalum (Ta), titanium (Ti), hafnium (Hf), zirconium (Zr), ruthenium (Ru), platinum (Pt), iridium (Ir), molybdenum (Mo) or aluminum (Al).

16. A method of fabricating a semiconductor device, comprising:
preparing a semiconductor substrate;
forming first semiconductor element regions configured to comprise first semiconductor elements of first conductivity type, and second semiconductor element regions configured to comprise second semiconductor elements of second conductivity type are to be formed, on the semiconductor substrate; and
forming the element separation regions between the first semiconductor element regions and the second semiconductor element regions, in order to form the first semiconductor element regions at the locations higher than those of the element separation regions next to the first semiconductor element regions.

17. The method of fabricating a semiconductor device of claim 16, wherein the forming the first semiconductor element regions at the locations higher than those of the element separation regions next to the first semiconductor element regions comprises keeping the distances from the surfaces of the element separation regions to the surfaces of the first semiconductor element regions shorter than gate widths of the first semiconductor element regions from a top view.

18. The method of fabricating a semiconductor device of claim 16, wherein the first semiconductor element regions are at the locations higher than those of the second semiconductor element regions.

19. The method of fabricating a semiconductor device of claim 16, wherein the second semiconductor element regions are at the substantially same locations in height as those of the element separation regions next to the second semiconductor element regions.

20. The method of fabricating a semiconductor device of claim 16, wherein the second semiconductor element regions are at the locations lower than those of the element separation regions next to the second semiconductor element regions.
